(19) United States
(12) Patent Application Publication
(10) Pub. No.: US 2019/0386249 A1
(43) Pub. Date: Dec. 19, 2019

(54) ENCAPSULATION METHOD, ENCAPSULATING STRUCTURE OF ORGANIC ELECTROLUMINESCENT DEVICE, AND DISPLAY APPARATUS

(71) Applicant: Wuhan China Star Optoelectronics Semiconductor Display Technology Co., Ltd., Wuhan, Hubei (CN)

(72) Inventors: Fenghao CAI, Shenzhen, Guangdong (CN); Jeoung Kwen NOH, Shenzhen, Guangdong (CN); Donghwan KIM, Shenzhen, Guangdong (CN); Young Su KIM, Shenzhen, Guangdong (CN); Chienlin WU, Shenzhen, Guangdong (CN); Xuwen CAO, Shenzhen, Guangdong (CN)

(21) Appl. No.: 15/754,118

(22) PCT Filed: Dec. 21, 2017
(86) PCT No.: PCT/CN2017/117737

§ 371 Date: Feb. 21, 2018

(30) Foreign Application Priority Data
Jul. 25, 2017 (CN) 201710614105.X

(51) Int. Cl. H01L 51/52; H01L 51/56; H01L 51/00; H01L 27/32

(52) U.S. Cl. CPC H01L 51/5256; H01L 51/56; H01L 2251/5338; H01L 27/32; H01L 51/0097

(57) ABSTRACT

The disclosure provides an encapsulation method and an encapsulating structure of an organic electroluminescent device, and a display apparatus. The encapsulation method of an organic electroluminescent device includes: providing a flexible substrate; forming an electrode layer on the flexible substrate; sequentially forming an inorganic layer on a surface of the electrode layer and an organic layer stacked on a surface of the inorganic layer, and a multilayer structure is formed by the inorganic layer and the organic layer alternately stacked with each other, the inorganic layer is formed by a chemical deposition method, and the organic layer is formed by printing; and dry etching the multilayer structure to form a thin film encapsulation layer. The disclosure has the advantages of low production cost and can solve the problems of high material cost, difficult maintenance, and poor film quality caused by the need of using the mask in the prior art.

### RELATED APPLICATIONS

The present application is a National Phase of International Application Number PCT/CN2017/117737, filed Dec. 21, 2017, and claims the priority of China Application No. 201710614105.X, filed Jul. 25, 2017.

### FIELD OF THE DISCLOSURE

The disclosure relates to the field of organic electroluminescence, and in particular to an encapsulation method of an encapsulating structure of an organic electroluminescent device, and a display apparatus.

### BACKGROUND

Organic electroluminescent device, also called organic electroluminescent diode (OLED) device, is a brand-new display technology used in the display apparatus, its display quality can be compared with the thin film transistor liquid crystal display, and its price is relatively low. OLED has become a hot spot in international research due to it has obvious advantages in flat display, such as high luminance, rich color, low voltage direct current driving, and simple manufacturing process. Therefore, OLED has been from the research into industrialization stage in less than 20 years.

The organic electroluminescent device is generally formed by using a rigid glass substrate or a flexible polymer substrate as a carrier by depositing the cathode and anode electrodes and two or more organic light-emitting layers sandwiched therebetween. Organic electroluminescent devices are very sensitive to oxygen and moisture. If oxygen or moisture penetrates into the organic light-emitting device, problems such as black spots, pinholes, oxidation of the electrodes, and poor chemical reaction of the organic material may occur, so that encapsulation technology is one of the key technologies to realize the industrialization of organic electroluminescent devices.

Conventional encapsulation technologies include metal cap encapsulation and glass cap encapsulation, both of which have superior water-oxygen barrier capabilities, but the metal cap is opaque and not suitable for many applications, while the glass cap has a low mechanical strength shortcoming. In addition, both of the two encapsulation methods require that a sealant be applied around the organic light-emitting region and a moisture absorber be placed therein, thus making the size of the display device relatively thick and failing to meet people's demands for flexibility and thinning of the organic electroluminescent device. Therefore, the development of thin film encapsulation technology has great necessity.

In the conventional flexible display, the organic light-emitting diode is usually fabricated on a flexible substrate. However, since the flexible display substrate has less resistance to water and oxygen than the glass substrate, in order to extend the service life of the flexible display, it is usually necessary to effectively encapsulate the organic light emitting diode on the flexible substrate. At present, the most effective organic light-emitting diode (OLED) encapsulation method usually uses the enhanced plasma chemical deposition method to make the encapsulation by cross-making a multilayer structure of the organic and the inorganic thin films on the flexible substrate by using a mask. However, the method requires a large number of masks to be used, and the masks need to be periodically cleaned. Therefore, the material cost is relatively high, and the maintenance is difficult. Once the cleaning is not performed in time, the film quality problems may occur.

### SUMMARY

The disclosure aims to solve one of the above technical problems at least to some extent, or at least to provide a useful business choice. For this reason, an object of the disclosure is to provide an encapsulation method of an organic electroluminescent device, which can better solve the problems due to the need of using a mask in the prior art, such as high material cost, difficult maintenance, and thin film quality problems caused by the mask not timely cleaned.

An encapsulation method of an organic electroluminescent device according to the disclosure, including:

step 1: providing a flexible substrate;

step 2: forming an electrode layer on the flexible substrate;

step 3: sequentially forming an inorganic layer on a surface of the electrode layer and an organic layer stacked on a surface of the inorganic layer, and the inorganic layer and the organic layer form a multilayer structure alternately stacked with each other, the inorganic layer is formed by a chemical deposition method, and the organic layer is formed by printing; and

step 4: dry etching the multilayer structure to form a thin film encapsulation layer.

Further, the chemical deposition method is an enhanced plasma chemical deposition method.

Further, the inorganic layer formed by the enhanced plasma chemical deposition method is an inorganic thin film layer made of Si3N4.

Further, the organic layer formed by printing on the surface of the inorganic layer is an organic layer formed by inkjet printing.

Further, the multilayer structure includes four layers of the inorganic layer and the organic layer.

Further, the four layers of the inorganic layer and the organic layer stacked with each other are dry-etched to form a thin film encapsulation layer.

Another object of the disclosure is to provide an encapsulating structure, which has a lower production cost and better solves the problem of the film quality caused by the not timely cleaning of the mask used in the production process in the prior art, including: a flexible substrate configured to support the organic electroluminescent device;

an electrode layer disposed on the flexible substrate;

a thin film encapsulation layer covering the electrode layer, and the thin film encapsulation layer includes a multilayer structure of an inorganic layer and an organic layer alternately stacked with each other and sequentially formed on the electrode layer, the inorganic layers being formed by a chemical deposition method, and the organic layer is formed by printing.

Further, the inorganic layer is an inorganic layer formed by an enhanced plasma chemical deposition method, and the inorganic layer is an inorganic thin film layer made of Si3N4.

Further, the organic layer is an organic layer formed by inkjet printing.

The disclosure further provides a display apparatus, including the encapsulating structure of the organic electroluminescent device, and the display apparatus with the encapsulating structure has lower production cost and better market competitiveness.

Additional aspects and advantages of the disclosure are set forth in part in the description which follows, and in part will be apparent from the description, or from the practice of the disclosure.

### BRIEF DESCRIPTION OF THE DRAWINGS

The above and/or other advantages of the disclosure will become readily apparent by reference to the following detailed description when considered in conjunction with the accompanying drawings wherein:

FIG. 1 is a flow chart of an encapsulation method of an organic electroluminescent device according to an embodiment of the disclosure; and

FIG. 2 is a schematic view of an encapsulating structure of an organic electroluminescent device of the disclosure.

### DETAILED DESCRIPTION OF PREFERRED EMBODIMENTS

The embodiments of the disclosure are described in detail below, and examples of the embodiments are shown in the accompanying drawings, wherein same or similar reference numerals denote same or similar elements or elements having the same or similar functions from beginning to end. The embodiments described below with reference to the accompanying drawings are exemplary and are intended to explain the disclosure and should not be construed as limiting the disclosure.

The embodiment of the disclosure provides an encapsulation method of an organic electroluminescent device. In the embodiment, the disclosure can solve the problems of high material cost, difficult maintenance, and poor film quality caused by the mask not timely cleaned due to the need of using the mask in the prior art.

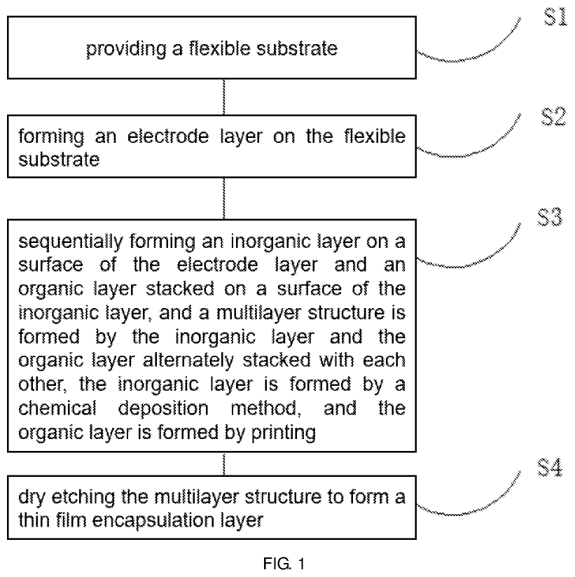

FIG. 1 is a flowchart of an encapsulation method according to an embodiment of the disclosure.

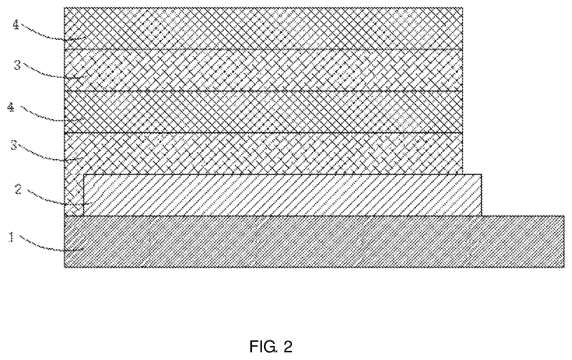

FIG. 2 is a schematic diagram of an encapsulating structure according to an embodiment of the disclosure.

With reference to FIG. 1 and FIG. 2, the disclosure provides an encapsulation method of an organic electroluminescent device, including:

step S1: providing a flexible substrate 1;

step S2: forming an electrode layer 2 on the flexible substrate 1;

step S3: sequentially forming an inorganic layer 3 on a surface of the electrode layer 2 and an organic layer 4 stacked on a surface of the inorganic layer 3, and a multilayer structure is formed by the inorganic layer 3 and the organic layer 4 alternately stacked with each other.

Specifically, in step S3, at first, the inorganic layer 3 is formed on the surface of the electrode layer 2 by a chemical deposition method. Next, the organic layer 4 is formed on the surface of the inorganic layer 3 by printing. Then, the inorganic layer 3 and the inorganic layer 4 are sequentially formed on the surface of the organic layer 4, and repeat the step to form a multilayer structure of the inorganic layers 3 and the organic layers 4 alternately stacked with each other.

Step S4: dry etching the multilayer structure to form a thin film encapsulation layer.

In the organic electroluminescent encapsulation method of the disclosure, by forming the inorganic layer 3 by a chemical deposition method on the surface of the electrode layer 2 and forming the organic layer 4 by printing on the surface of the inorganic layer 3, then, sequentially forming the inorganic layer 3 on the surface of the organic layer 4 and the inorganic layer 4 on the inorganic layer 3, and repeating the step, so as to form a multilayer structure of the inorganic layer 3 and the organic layer 4 alternately stacked with each other. And by dry etching the multilayer structure to form the thin film encapsulation layer, the purpose of encapsulating the organic electroluminescent device is achieved. Since there is no need to encapsulate by using a mask as in the prior art, the high cost of the mask material is decreased, and the manufacturing cost is reduced. And the difficulty of maintenance due to the use of a mask is effectively reduced, thereby reducing the film quality problems caused by the not timely maintenance.

During the specific implementation process, in step S3, the preferred chemical deposition method is an enhanced plasma chemical deposition method. The inorganic layer 3 formed by the enhanced plasma chemical deposition method is preferably an inorganic thin film layer made of Si3N4.

A specific implementation process, in step S3, the organic layer 4 formed by printing on the surface of the inorganic layer 3 is the organic layer 4 formed by inkjet printing. Inkjet printing is that a nozzle picks up the probe reagent from the microplate and moves to a treated support, through the thermal or voice control ejector power, the droplet is jetted to the support surface, and tiny black or color material is ink-jetted onto the desired area.

During the specific implementation, preferably, the multilayer structure includes four layers of inorganic layer 3 and organic layer 4. The four layers of inorganic layer 3 and organic layer 4 stacked with each other are dry-etched to form a thin film encapsulation layer. By using the dry etching method, part of the multilayer of inorganic layer 3 is protected by the printed organic layer 4 and part of the multilayer of inorganic layer 3 is not protected by the organic layer 4. Under dry etching, the part of the inorganic layer not protected by the organic layer reacts with the reactant of dry etching and is etched by the reactant, and the part of the inorganic layer protected by the organic layer 4 is not etched by the reactant. After the dry etching, the inorganic layer 3 is partially etched to expose the electrode needing to be exposed, thus the film encapsulation process is completed.

Another object of an embodiment of the disclosure is to provide an encapsulating structure, which has a lower production cost and better solves the problem of film quality caused by not timely cleaning of the mask used in the manufacturing process in the prior art.

Continuing with the accompanying drawings, the encapsulating structure of the organic electroluminescent device includes: a flexible substrate 1 configured to support the organic electroluminescent device; an electrode layer 2 disposed on the flexible substrate 1; a thin film encapsulation layer covering the electrode layer 2, and the thin film encapsulation layer includes a multilayer of the inorganic layer 3 and the organic layer 4 alternatively stacked with each other and sequentially formed on the surface of the electrode layer 2. The inorganic layer 3 is formed by a chemical deposition method, and the organic layer 4 is formed by printing. A thin film encapsulation layer is formed by the inorganic layer 3 and the organic layer 4 stacked with each other by dry etching. By using the chemical deposition method and the printing method to form the inorganic layer 3 and the organic layer 4 respectively, the use of the metal mask in the production process may be effectively reduced, thereby reducing the production cost and reducing the problem of the film quality brought from not timely maintenance in the production process.

During the specific implementation, the inorganic layer 3 is preferably an inorganic layer 3 formed by a plasma enhanced chemical deposition method, and the inorganic material layer 3 is an inorganic thin film layer made of Si3N4.

During the specific implementation, the organic layer is preferably an organic layer 4 formed by inkjet printing.

The disclosure further provides a display apparatus, which includes the encapsulating structure of the organic electroluminescent device, and the display apparatus with the encapsulating structure described above has lower production cost and better market competitiveness.

Reference throughout this specification to “one embodiment,” “some embodiments,” “an example,” “a specific example,” or “some examples” and the like means that a specific feature, structure, material or characteristic described in connection with the embodiment or example are included in at least one embodiment or example of the disclosure. In this specification, the schematic representation of the terms is not necessarily all referring to the same embodiment or example. Furthermore, the specific features, structures, materials or characteristics may be combined in any suitable manner in one or more embodiments or examples.

Although the embodiments of the disclosure have been shown and described above, it should be understood that the embodiments are merely exemplary and should not be construed as limiting the disclosure. Those skilled in the art can make changes, modifications, substitutions and variations to the embodiments within the scope of the disclosure without departing from the principle and purpose of the disclosure.

What is claimed is:

1. An encapsulation method of an organic electroluminescent device, comprising:
step 1: providing a flexible substrate;
step 2: forming an electrode layer on the flexible substrate;
step 3: sequentially forming an inorganic layer on a surface of the electrode layer and an organic layer stacked on a surface of the inorganic layer, wherein the inorganic layer and the organic layer form a multilayer structure alternately stacked with each other, the inorganic layer is formed by a chemical deposition method, and the organic layer is formed by printing; and
step 4: dry etching the multilayer structure to form a thin film encapsulation layer.

2. The encapsulation method of the organic electroluminescent device according to claim 1, wherein the chemical deposition method is an enhanced plasma chemical deposition method.

3. The encapsulation method of the organic electroluminescent device according to claim 2, wherein the inorganic layer formed by the enhanced plasma chemical deposition method is an inorganic thin film layer made of Si3N4.

4. The encapsulation method of the organic electroluminescent device according to claim 1, wherein the organic layer formed by printing on the surface of the inorganic layer is by inkjet printing.

5. The encapsulation method of the organic electroluminescent device according to claim 1, wherein the multilayer structure comprises four layers of the inorganic layer and the organic layer stacked with each other.

6. The encapsulation method of the organic electroluminescent device according to claim 2, wherein the multilayer structure comprises four layers of the inorganic layer and the organic layer stacked with each other.

7. The encapsulation method of the organic electroluminescent device according to claim 3, wherein the multilayer structure comprises four layers of the inorganic layer and the organic layer stacked with each other.

8. The encapsulation method of the organic electroluminescent device according to claim 4, wherein the multilayer structure comprises four layers of the inorganic layer and the organic layer stacked with each other.

9. The encapsulation method of the organic electroluminescent device according to claim 5, wherein the four layers of the inorganic layer and the organic layer stacked with each other are dry-etched to form a thin film encapsulation layer.

10. The encapsulation method of the organic electroluminescent device according to claim 6, wherein the four layers of the inorganic layer and the organic layer stacked with each other are dry-etched to form a thin film encapsulation layer.

11. The encapsulation method of the organic electroluminescent device according to claim 7, wherein the four layers of inorganic layer and organic layer stacked with each other are dry-etched to form a thin film encapsulation layer.

12. The encapsulation method of the organic electroluminescent device according to claim 8, wherein the four layers of inorganic layer and organic layer stacked with each other are dry-etched to form a thin film encapsulation layer.

13. An encapsulating structure of an organic electroluminescent device, comprising:
a flexible substrate configured to support the organic electroluminescent device;
an electrode layer disposed on the flexible substrate; and
a thin film encapsulation layer covering the electrode layer, wherein the thin film encapsulation layer comprises a multilayer structure of an inorganic layer and an organic layer alternatively stacked with each other and sequentially formed on a surface of the electrode layer, the inorganic layer is formed by a chemical deposition method, and the organic layer is formed by printing.

14. The encapsulating structure of the organic electroluminescent device according to claim 13, wherein the inorganic layer is formed by an enhanced plasma chemical deposition method, and the inorganic layer is an inorganic thin film layer made of Si3N4.

15. The encapsulating structure of the organic electroluminescent device according to claim 13, wherein the organic layer is formed by inkjet printing.

16. A display apparatus, comprising:
an encapsulating structure of an organic electroluminescent device, comprising:
a flexible substrate configured to support the organic electroluminescent device;
an electrode layer disposed on the flexible substrate; and
a thin film encapsulation layer covering the electrode layer;
wherein the thin film encapsulation layer comprises a multilayer structure of an inorganic layer and an organic layer alternatively stacked with each other and sequentially formed on a surface of the electrode layer, the inorganic layer is formed by a chemical deposition method, and the organic layer is formed by printing.

17. The display apparatus according to claim 16, wherein the inorganic layer is formed by an enhanced plasma chemical deposition method, and the inorganic layer is an inorganic thin film layer made of Si3N4.

18. The display apparatus according to claim 17, wherein the organic layer is formed by inkjet printing.
